(19) United States
(12) Patent Application Publication
(10) Pub. No.: US 2025/0238690 A1
(43) Pub. Date: Jul. 24, 2025

(54) Machine Learning Based Semiconductor Measurement Models Trained Using Historical Data

(71) Applicant: KLA Corporation, Milpitas, CA (US)

(72) Inventor: Zhengquan Tan, Cupertino, CA (US)

(21) Appl. No.: 18/760,323

(22) Filed: Jul. 1, 2024

Related U.S. Application Data
(60) Provisional application No. 63/622,592, filed on Jan. 19, 2024.

(51) Int. Cl. G06N 5/022; H01L 21/67

(52) U.S. Cl. CPC G06N 5/022; H01L 21/67288

(57) ABSTRACT

Methods and systems for using historical measurement data to train a present state, machine learning (ML) based measurement model are described herein. This approach takes advantage of the correlation between structural characteristics of measured samples fabricated in accordance with different design revisions, process revisions, or both. In one aspect, a present state, ML based measurement model is trained using training data associated with measurements of a plurality of instances of a current version of a semiconductor structure in a present state of a semiconductor process flow and training data associated with measurements of a plurality of instances of a historical version of the semiconductor structure in the present state of the semiconductor process flow. In some examples, training data also includes prior state measurement data. Historical training data, prior state training data, or both, may be derived from actual reference measurements, in-line, production measurements, or both.

### TECHNICAL FIELD

The described embodiments relate to metrology systems and methods, and more particularly to methods and systems for improved measurement accuracy.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical and x-ray based metrology techniques offer the potential for high throughput without the risk of sample destruction. A number of techniques including scatterometry and reflectometry implementations and associated analysis algorithms are commonly used to characterize critical dimensions, film thicknesses, composition and other parameters of nanoscale structures.

As devices (e.g., logic and memory devices) move toward smaller nanometer-scale dimensions, characterization becomes more difficult. Devices incorporating complex three-dimensional geometry and materials with diverse physical properties contribute to characterization difficulty. In general, semiconductor device shapes and profiles are changing dramatically along with new process capabilities. In particular, advanced logic and memory devices must meet increasingly demanding specifications for Critical Dimension (CD) profiles. Thus, detailed features of geometric profiles must be measured accurately.

Significant advances in process chemistry have enabled new etch applications. In some examples, High Aspect Ratio (HAR) etch tools are capable of etching away very narrow vertical channels in semiconductor die with aspect ratios, i.e., ratio of height/width, of 80:1, or higher. This capability has enabled flash memory architectures to transition from two dimensional floating-gate architectures to fully three dimensional geometries. In some examples, film stacks and etched structures are very deep (e.g., three micrometers in depth, or more) and include an extremely high number of layers (e.g., 400 layers, or more).

As the etch process penetrates deeper into the structure, the etch rate is susceptible to change along the channel. This leads to a non-uniform etch profile, i.e., the Critical Dimension (CD) of a fabricated channel varies as a function of height. Typical semiconductor devices include millions of HAR channels separated from each other by extremely small distances, e.g., tens of nanometers. Thus, etch profile uniformity and parallelism of HAR channels must be controlled to very tight specifications to achieve an acceptable device yield.

High aspect ratio structures create challenges for film and CD measurements. The ability to measure the critical dimensions that define the shapes of holes and trenches of these structures is critical to achieve desired performance levels and device yield. The metrology must be capable of measuring the CD of a continuous profile through a deep channel to determine the location of CD variations and inflection points of profile variations.

In other examples, the most advanced memory and logic device structures, e.g., nanowire structures, forksheet structures, complementary field effect transistor (CFET) structures, multi-deck VNAND structures, etc., incorporate new complex three-dimensional geometry, dramatic topographic changes, and materials with diverse orientation and physical properties. These advanced devices are difficult to characterize.

In response to these challenges, more complex metrology tools have been developed. Measurements are performed over large ranges of several machine parameters (e.g., wavelength, azimuth and angle of incidence, etc.), and often simultaneously. As a result, the measurement time, computation time, and the overall time to generate reliable results, including measurement recipes and accurate measurement models, increases significantly.

Existing physical model based metrology methods typically include a series of steps to model and then measure structure parameters. Typically, measurement data (e.g., DOE spectra) is collected from a set of samples or wafers, a particular metrology target, a testing critical dimension target, an in-cell actual device target, an SRAM memory target, etc. An accurate model of the optical response from these complex structures including a model of the geometric features, dispersion parameter, and the measurement system is formulated. Typically, a regression is performed to refine the geometric model. In addition, simulation approximations (e.g., slabbing, Rigorous Coupled Wave Analysis (RCWA), etc.) are performed to avoid introducing excessively large errors. Discretization and RCWA parameters are defined. A series of simulations, analysis, and regressions are performed to refine the geometric model and determine which model parameters to float. A library of synthetic spectra is generated. Finally, measurements are performed using the library or regression in real time with the geometric model.

In other examples, machine learning model based metrology methods are employed to perform measurements. In these examples, training data are gathered and employed to train a machine learning based model that maps measured spectra to values of one or more parameters of interest.

In many fabrication scenarios, dimensions measured before and after a particular process step, or set of process steps, are correlated. Thus, in principle, pre-process measurement data may be employed to improve the accuracy of measurements of structures after one or more intervening process steps.

In some examples, pre-process measurement data are employed as part of a physical model based metrology method. In these examples, pre-process measurement data are fed forward to a post-process measurement model. This approach may be employed in a regression based solution using an RCWA solver where all model degrees of freedom are floated simultaneously. In these examples, the pre-process measurement data breaks parameter correlations among multiple interacting model parameters within the post-process measurement model. Unfortunately, RCWA solver based measurement methods have not shown promise for many measurement applications involving the most advanced memory and logic device structures.

Machine learning model based metrology methods have shown greater promise for many measurement applications involving the most advanced memory and logic device structures. However, pre-process measurement data cannot be directly fed forward to a post-process ML based measurement model because each floating parameter is resolved using an independently optimized ML model. Thus, there are no parameter correlations to be broken in an ML based measurement model. As a result, data feedforward of pre-process measurement data does not improve the accuracy of an ML model based measurement.

In general, the effectiveness of a ML based measurement model depends on the quality and quantity of reference training data. Training data must be gathered at high sampling frequency over a wide range of the process parameter space to meet the measurement application requirements involving the most advanced memory and logic device structures. Unfortunately, actual reference measurement data, e.g., Tunneling Electron Microscopy (TEM) measurements, Scanning Electron Microscopy (SEM) measurements, etc., are limited to a very small number of measurement sites on a wafer, e.g., less than 50 locations, for a particular measurement application. The lack of accurate reference measurement data collected from each wafer leaves vast portions of the process space unrepresented or underrepresented in the training data set. As a result, a ML based measurement model trained on sparse reference measurement data tends to inaccurately characterize structures fabricated within large portions of the process space.

In an attempt to overcome the lack of actual reference measurement data, training data are generated synthetically. In some examples, post-process synthetic data sets, e.g., spectra, are generated based on a physics based measurement model. The synthetic data sets are generated using an RCWA solver over a range of different parameter values that simulates the process space. The synthetically generated data sets are employed to train a ML based measurement model. In practice, however, synthetically generated training data do not capture all pre-process variation and cannot predict all the possible post-process variation before library generation. In some examples, pre-process variation occurs in parameters that are fixed in value when generating post-process synthetic data sets. As a result, the pre-process variation is not captured at all in the training data. In one example, pre-process process variation of a material optical dispersion occurs, yet the dispersion parameter is treated as fixed when generating post-process synthetic data sets.

In practice, the number of pre-process parameters that can be floated in a physics based measurement model is limited, e.g., 10-15 parameters, by concerns about model quality, time to solution, and the computational effort associated with library generation. Moreover, the number of pre-process parameters that actually vary greatly exceeds that number. As a result, the pre-process variation of many parameters is not captured in the post-process synthetic data sets, even when some pre-process parameters are floated when generating post-process synthetic data sets.

Modeling of emerging semiconductor structures has resulted in increasingly complicated models with unsatisfactory results. Machine learning model based metrology methods have shown promise for many measurement applications involving the most advanced memory and logic device structures. Unfortunately, the training data currently employed to train ML based measurement models is limiting the performance of trained ML based measurement models. In particular, pre-process measurement data that correlates with post-process parameters of interest is not adequately captured by the training data sets currently employed. As complex semiconductor structures become more common, and with less time per project, improved measurement model training methods and tools are desired.

### SUMMARY

Methods and systems for using historical measurement data to train a present state, machine learning (ML) based measurement model are described herein. This approach takes advantage of the correlation between structural characteristics of measured samples fabricated in accordance with different design revisions, process revisions, or both. In addition, prior state measurement data are employed to train a present state, ML based measurement model. This approach takes advantage of the correlation between structural characteristics of measured samples fabricated before and after one or more intervening process steps.

In one aspect, a present state, ML based measurement model is trained using training data associated with measurements of a plurality of instances of a current version of a semiconductor structure in a present state of a semiconductor process flow and training data associated with measurements of a plurality of instances of a historical version of the semiconductor structure in the present state of the semiconductor process flow.

A present state indicates the state of the semiconductor structure after the latest process step applied to the semiconductor structure, and before any subsequent process steps are applied to the semiconductor structure. A prior state indicates the state of the semiconductor structure before the latest process step was applied to the semiconductor structure. In some examples, a significant amount of validated measurement data is collected from a semiconductor structure in a prior state. In some of these examples, accurate measurements of one or more parameters of interest in a prior state are relatively easy to obtain compared to a present state. In this manner, measurement data associated with a semiconductor structure in a prior state are typically trusted. To the extent that a semiconductor structure in a prior state is reasonably correlated with a the semiconductor structure in a present state, prior state measurement data can be employed to improve the accuracy and reliability of a trained present state measurement model.

A version of a semiconductor structure indicates the design version of a semiconductor structure, a process recipe version employed to fabricate the semiconductor structure, or both. A current version of a semiconductor structure is the design revision, process recipe, or both, associated with semiconductor structure for which a present state measurement model is being trained. A historical version of the semiconductor structure is a different design revision, different process recipe, or both, associated with the semiconductor structure. Typically, a historical version of a semiconductor structure is an earlier design revision, earlier process recipe, or both, for which a significant amount of validated measurement data has been collected. In this manner, measurement data associated with historical versions of a semiconductor structure are typically trusted. To the extent that historical versions of semiconductor structure are reasonably correlated with a current version of the semiconductor structure, historical measurement data can be employed to improve the accuracy and reliability of a trained present state measurement model.

In one aspect, a training data set includes raw measurement signals associated with a measurement of each of the plurality of instances of the current version of the semiconductor structure in the present process state, and a corresponding measured value of the parameter of interest associated with a reference measurement of each of the plurality of instances of the current version of the semiconductor structure by a reference metrology system.

In some embodiments, the training data set also includes raw measurement signals associated with a measurement of each of a plurality of instances of a historical version of the semiconductor structure in the present process state, and a corresponding measured value of the parameter of interest associated with a reference measurement of each of the plurality of instances of the historical version of the semiconductor structure by a reference metrology system.

In some embodiments, a training data set also includes raw measurement signals associated with a measurement of each of a plurality of instances of a historical version of the semiconductor structure in the present process state, and a corresponding measured value of the measured parameter of interest associated with each of the plurality of instances of the historical version of the semiconductor structure by a high-throughput, in-line production metrology system.

In some embodiments, a training data set also includes a plurality of assumed values of a parameter of interest characterizing the current version of the semiconductor structure in the present process state and synthetically generated, raw measurement signals corresponding to each of the assumed values of the parameter of interest.

In some embodiments, a training data set includes raw measurement signals associated with a measurement of each of a plurality of instances of the current version of the semiconductor structure in a prior process state and a corresponding measured value of the parameter of interest associated with a reference measurement of each of the plurality of instances of the current version of the semiconductor structure by a reference metrology system.

In some embodiments, a training data set includes assumed values of a parameter of interest characterizing the current version of the semiconductor structure in a prior process state and synthetically generated, raw measurement signals corresponding to each of the assumed values of a parameter of interest.

In some embodiments, a training data set includes raw measurement signals associated with a measurement of each of a plurality of instances of a historical version of the semiconductor structure in a prior process state and a corresponding measured value of the parameter of interest associated with a reference measurement of each of the plurality of instances of the historical version of the semiconductor structure in the prior process state by a reference metrology system.

In some embodiments, a training data set includes raw measurement signals associated with a measurement of each of the plurality of instances of a historical version of the semiconductor structure in the present process state and a corresponding measured value of the measured parameter of interest associated with each of the plurality of instances of the historical version of the semiconductor structure by a high-throughput, in-line production metrology system. This training data set is derived from high-throughput, in-line measurements of historical instances of the structure of interest fabricated on one or more production wafers in the i^{th} prior state, where i is any non-zero positive integer number bounded by the total number of prior process states before the present process state in the semiconductor fabrication process flow.

In general, training data sets may include training data associated with historical, prior state measurements at any number of prior process steps. Each of the different prior states of the semiconductor process flow and the present state of the semiconductor process flow are separated by one or more intervening semiconductor manufacturing process steps. Furthermore, each of the different prior states of the semiconductor process flow and any other of the different prior states are separated by one or more intervening semiconductor manufacturing process steps.

In some examples, training data continues to be generated based on reliable, high-throughput, in-line measurements of a continuously growing number of instances of a structure of interest at a prior state, along with corresponding high-throughput, in-line measurement signals in the present state. In these examples, prior state and present state measurements continue to be collected from in-line, production wafers. Periodically, the expanded set of training data is employed to retrain the present state measurement model to continuously improve the accuracy and reliability of the trained present state measurement model as production continues.

In a further aspect, a present state measurement model training engine includes a weighting module that assigns different weighting values to different sets of training data. The relative weighting of different sets of training data emphasizes training data sets assigned a relatively high weighting and deemphasizes training data sets assigned a relatively low weighting. In this manner, training data sets associated with a higher level of trust in the data or higher correlation to the current version of the structure of interest in the present state are emphasized over training data sets that are less trusted or have lower correlation to the current version of the structure of interest in the present state.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of an embodiment of a spectroscopic ellipsometry system for measuring characteristics of a semiconductor wafer based on a trained present state measurement model as described herein.

FIG. 2 is a diagram illustrative of a present state measurement engine 150 configured to estimate values of one or more parameters of interest characterizing a semiconductor structure in a present state as described herein.

FIG. 3 is a diagram illustrative of a present state measurement model training engine configured to train a present state measurement model as described herein.

FIG. 4 is a diagram illustrative of a nanowire based semiconductor structure in one embodiment.

FIG. 5 is a diagram illustrative of a nanosheet based semiconductor structure in a prior state in one embodiment.

FIG. 6 is a diagram illustrative of the nanosheet based semiconductor structure depicted in FIG. 5 in a present state in one embodiment.

FIG. 7 is a plot illustrative of correlation between the width of inner spacer structures immediately after the epitaxial growth step and immediately after the SiGe release step.

FIG. 8 is a plot illustrative of correlation between the critical dimension, MGCD₁, depicted in FIG. 7 immediately after the epitaxial growth step and immediately after the SiGe release step.

FIG. 9 is a plot illustrative of correlation between the critical dimension, MGCD₂, depicted in FIG. 7, immediately after the epitaxial growth step and immediately after the SiGe release step.

FIG. 10 is a plot illustrative of correlation between the critical dimension, MGCD₃, depicted in FIG. 7, immediately after the epitaxial growth step and immediately after the SiGe release step.

FIG. 11 illustrates a method 300 for training a present state measurement model as described herein.

### DETAILED DESCRIPTION

Reference will now be made in detail to background examples and some embodiments of the invention, examples of which are illustrated in the accompanying drawings.

Methods and systems for using historical measurement data to train a present state, machine learning (ML) based measurement model are described herein. Historical measurement data are employed as part of the training data set for a present state, ML based measurement model to take advantage of the correlation between structural characteristics of measured samples fabricated in accordance with different design revisions, process revisions, or both.

In addition, methods and systems for using prior state measurement data to train a present state, machine learning (ML) based measurement model are described herein. Prior state measurement data are employed as part of the training data set for a present state, ML based measurement model to take advantage of the correlation between structural characteristics of measured samples fabricated before and after one or more intervening process steps.

The methods and systems described herein improve measurement accuracy and robustness for cutting-edge measurement applications involving Gate All Around (GAA) structures, Fork Sheet structures, CFET structures, 3D VNAND structures, 3D DRAM structures, etc. In one example, the methods and systems described herein improve critical dimension measurements of a GAA SRAM structure after a Sheet Formation process step.

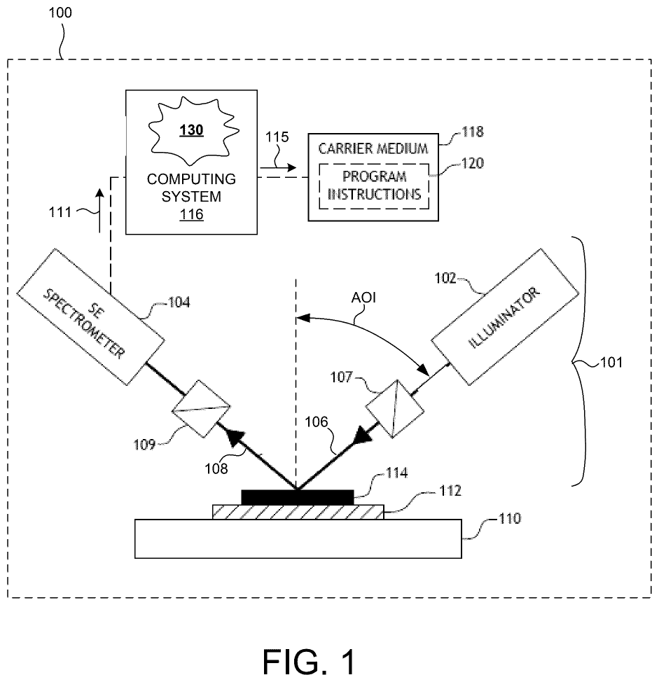

FIG. 1 illustrates a system 100 for measuring characteristics of a semiconductor wafer. As shown in FIG. 1, system 100 may be used to perform spectroscopic ellipsometry measurements of one or more structures 114 of a semiconductor wafer 112 disposed on a wafer positioning system 110. In this aspect, the system 100 may include a spectroscopic ellipsometer equipped with an illuminator 102 and a spectrometer 104. The illuminator 102 of the system 100 is configured to generate and direct illumination of a selected wavelength range (e.g., 150-4500 nm) to the structure 114 disposed on the surface of the semiconductor wafer 112. In turn, the spectrometer 104 is configured to receive light from the surface of the semiconductor wafer 112. It is further noted that the light emerging from the illuminator 102 is polarized using a polarization state generator 107 to produce a polarized illumination beam 106. The radiation reflected by the structure 114 disposed on the wafer 112 is passed through a polarization state analyzer 109 and to the spectrometer 104. The radiation received by a detector of spectrometer 104 in the collection beam 108 is analyzed with regard to polarization state, allowing for spectral analysis of radiation passed by the analyzer. These spectra 111 are passed to the computing system 116 for analysis of the structure 114.

In a further embodiment, the metrology system 100 is a measurement system 100 that includes one or more computing systems 116 configured to execute present state measurement tool 150 in accordance with the description provided herein. In the preferred embodiment, present state measurement tool 150 is a set of program instructions 120 stored on a carrier medium 118. The program instructions 120 stored on the carrier medium 118 are read and executed by computing system 116 to realize model based measurement functionality as described herein. The one or more computing systems 116 may be communicatively coupled to the spectrometer 104. In one aspect, the one or more computing systems 116 are configured to receive measurement data 111 associated with a measurement (e.g., critical dimension, film thickness, composition, process, etc.) of the structure 114 of specimen 112. In one example, the measurement data 111 includes an indication of the measured spectral response (e.g., measured intensity as a function of wavelength) of the specimen by measurement system 100 based on the one or more sampling processes from the spectrometer 104. In some embodiments, the one or more computing systems 116 are further configured to determine specimen parameter values of structure 114 from measurement data 111.

In a further aspect, computing system 116 is configured to determine dimensions of a sample by providing present state raw measurement signals, e.g., measurement data 111 collected from a sample in a present state, as input to a trained present state measurement model. The trained present state measurement model is a machine learning based measurement model that determines dimensions of a sample based on measurement data provided as input to the model.

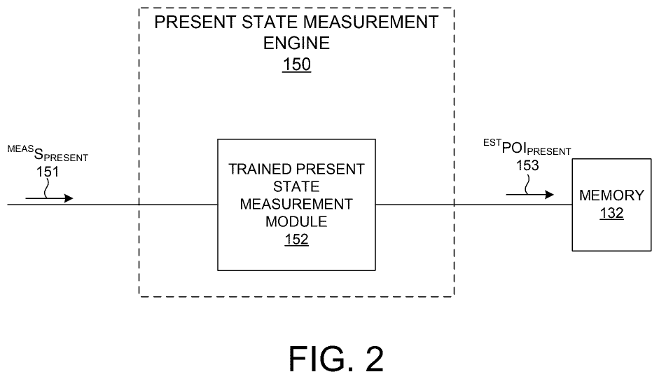

In the embodiment depicted in FIG. 2, computing system 116 is configured as a present state measurement engine 150 configured to implement model based measurement functionality as described herein. As depicted in FIG. 2, present state measurement engine 150 includes a trained, present state measurement module 152. Trained present state measurement module 152 includes a trained present state measurement model that generates estimated values of one or more parameters of interest, ^{EST}POI_{PRESENT} 153, characterizing the shape of a structure under measurement in a present state, i.e., after a particular process step, based on raw measurement signals, ^{MEAS}S_{PRESENT} 151, collected from the structure under measurement in the present state.

In one example, illuminator 102 illuminates an instance of a current version of a semiconductor structure in a present state of a semiconductor process flow with an amount of radiation 106. Spectrometer 104 detects raw measurement signals from the instance of the current version of the semiconductor structure in response to the incident radiation. Computing system 116 provides the measurement signals as input to a trained present state, machine learning based measurement model. The trained present state machine learning based measurement model estimates a value of a parameter of interest characterizing the instance of the current version of the semiconductor structure in the present state. The estimated value of the parameter of interest is an output of the trained, present state, machine learning based measurement model generated in response to the raw measurement signals provided as input.

In some examples, measurements are performed at N different instances of a semiconductor structure fabricated at different locations, different wafers, or both, where N is any positive integer value. Specimen parameters of interest can be deterministic (e.g., CD, SWA, etc.) or statistical (e.g., rms height of sidewall roughness, roughness correlation length, etc.).

In some embodiments, measurement system 100 is further configured to store one or more trained present state measurement models in a memory (e.g., carrier medium 118).

In one aspect, a present state, ML based measurement model is trained using training data associated with measurements of a plurality of instances of a current version of a semiconductor structure in a present state of a semiconductor process flow and training data associated with measurements of a plurality of instances of a historical version of the semiconductor structure in the present state of the semiconductor process flow.

A state of a semiconductor structure indicates the particular state of semiconductor structure within a semiconductor fabrication process flow. For example, a present state indicates the state of the semiconductor structure after the latest process step applied to the semiconductor structure, and before any subsequent process steps are applied to the semiconductor structure. A prior state indicates the state of the semiconductor structure before the latest process step was applied to the semiconductor structure. A semiconductor fabrication process flow includes many process steps, e.g., over one hundred process steps. As such, for a typical present state of a complex semiconductor structure there are many prior states of semiconductor structure.

In some examples, a significant amount of validated measurement data is collected from a semiconductor structure in a prior state. In some of these examples, accurate measurements of one or more parameters of interest in a prior state are relatively easy to obtain compared to a present state. In this manner, measurement data associated with a semiconductor structure in a prior state are typically trusted. To the extent that a semiconductor structure in a prior state is reasonably correlated with a the semiconductor structure in a present state, prior state measurement data can be employed to improve the accuracy and reliability of a trained present state measurement model.

A version of a semiconductor structure indicates the design version of a semiconductor structure, a process recipe version employed to fabricate the semiconductor structure, or both. For example, a current version of a semiconductor structure is the design revision, process recipe, or both, associated with semiconductor structure for which a present state measurement model is being trained. A historical version of the semiconductor structure is a different design revision, different process recipe, or both, associated with the semiconductor structure. Typically, a historical version of a semiconductor structure is an earlier design revision, earlier process recipe, or both, for which a significant amount of validated measurement data has been collected. In this manner, measurement data associated with historical versions of a semiconductor structure are typically trusted. To the extent that historical versions of semiconductor structure are reasonably correlated with a current version of the semiconductor structure, historical measurement data can be employed to improve the accuracy and reliability of a trained present state measurement model.

Measurements of parameters of interest at a present state using a present state measurement model trained using training data associated with both a current version and one or more historical versions of a semiconductor structure are generally more robust and more accurate compared to measurements performed using a present state measurement model trained using only training data associated with a current version of the semiconductor structure.

In some examples, training a present state, ML based measurement model using training data associated with both a current version and one or more historical versions of a semiconductor structure dramatically shortens the time required to generate an accurate and reliable measurement model.

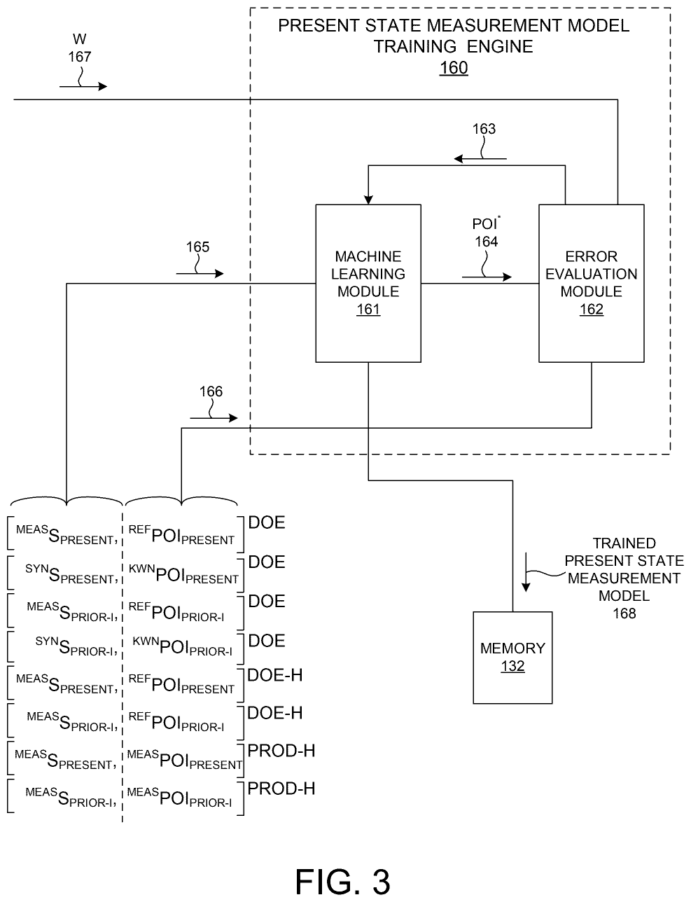

In a further aspect, computing system 116 is configured to train a present state measurement model based at least in part training data associated with both a current version and one or more historical versions of a semiconductor structure. In the embodiment depicted in FIG. 3, computing system 116 is configured as a present state measurement training engine 160.

As depicted in FIG. 3, present state measurement model training engine 160 includes a machine learning module 161 and an error evaluation module 162. As depicted in FIG. 3, training data set 165 associated with raw measurement signals is communicated to machine learning module 161, and training data set 166 including corresponding values of a parameter of interest is communicated to error evaluation module 162.

Training data sets 165 and 166 are extracted from sets of paired measurement data derived from a number of different reference data sources as described herein. Each set of paired measurement data includes raw measurement signals, e.g., spectral measurements, diffraction images, etc., associated with measurements of a number of instances of the structure of interest and corresponding values of a parameter of interest characterizing a structural characteristic of the structure of interest. Training data set 165 includes the raw measurement signals associated with each set of paired measurement data, and training data set 166 includes the corresponding values of the parameter of interest associated with each set of paired measurement data included in training set 165.

In some examples, machine learning module 161 generates estimated values of one or more parameters of interest, POI* 164, based on each set of raw measurement signals comprising the training data set 165. Error evaluation module 162 receives the estimated values of the one or more parameters of interest, POI* 164, generated by machine learning module 161. In addition, error evaluation module 162 receives training data set 166 including the corresponding values of the parameter of interest characterizing associated with each set of raw measurement signals included in training data set 165. The values of training set 166 indicate trusted values of the one or more parameters of interest associated with each set of raw measurement signals included in training data set 165. Error evaluation module 162 generates updated values of weighting parameters 163 of the machine learning model 161 undergoing training to minimize differences between the estimated values of the one or more parameters of interest, POI* 164, and the trusted values of the one or more parameters of interest associated with each set of measurement signals. In the next iteration of model training, new estimated values of the one or more parameters of interest, POI* 164, are generated by machine learning module 161 based on the values of the weighting parameters 163 generated in the previous iteration. The training process continues until the differences between the estimated values of the one or more parameters of interest, POI* 164, and the trusted values of the one or more parameters of interest associated with each set of measurement signals are acceptably small. At this point, the trained present state measurement model 168 is stored in a memory, e.g., memory 132.

In one aspect, training data set 165 includes raw measurement signals associated with a measurement of each of the plurality of instances of the current version of the semiconductor structure in the present process state, [^{MEAS}S_{PRESENT}]^{DOE}, and training data set 166 includes a corresponding measured value of the parameter of interest associated with a reference measurement of each of the plurality of instances of the current version of the semiconductor structure by a reference metrology system, [^{REF}POI_{PRESENT}]^{DOE}. This measurement data pair, [^{MEAS}S_{PRESENT}, ^{REF}POI_{PRESENT}]^{DOE}, is derived from measurements of instances of the structure of interest fabricated on one or more Design Of Experiments (DOE) wafers in the present state. The DOE wafers are typically off-line wafers purposely fabricated with variations in process parameters to probe the expected process space and ensure that the measurement model is trained to reliably perform measurements of structures fabricated within the expected process window during high volume production.

For many process steps of a complex semiconductor structure, reliable, actual reference measurements are only available from low throughput, expensive, and often destructive measurement techniques, e.g., Transmission Election Microscopy (TEM), Scanning Electron Microscopy (SEM), etc. Thus, in practice, it is not feasible to generate very large reference data sets based on actual reference measurement data generated by trustworthy reference measurement systems for many process steps. In response, historical measurement data are employed to overcome the lack of actual reference measurement data collected at a limited number of different locations on a limited number of different wafers.

In some embodiments, training data set 165 includes raw measurement signals associated with a measurement of each of the plurality of instances of a historical version of the semiconductor structure in the present process state, [^{MEAS}S_{PRESENT}]^{DOE-H}, and training data set 166 includes a corresponding measured value of the parameter of interest associated with a reference measurement of each of the plurality of instances of the historical version of the semiconductor structure by a reference metrology system, [^{REF}POI_{PRESENT}]^{DOE-H}. This measurement data pair, [^{MEAS}S_{PRESENT}, ^{REF}POI_{PRESENT}]^{DOE-H}, is derived from measurements of historical instances of the structure of interest fabricated on one or more Design Of Experiments (DOE) wafers in the present state. The historical DOE wafers (DOE-H) are typically off-line wafers purposely fabricated with variations in process parameters to probe the expected process space during measurement recipe development for a historical version of the structure of interest. Although, the design revision, process revision, or both, associated with the historical version is not exactly the same as the current version of the structure of interest, this historical training data is available, validated, and correlated with the current version. As such, this historical training data contributes to the training of a present state measurement model that reliably performs measurements of structures fabricated within the expected process window during high volume production.

In some embodiments, training data set 165 includes raw measurement signals associated with a measurement of each of the plurality of instances of a historical version of the semiconductor structure in the present process state, [^{MEAS}S_{PRESENT}]^{PROD-H}, and training data set 166 includes a corresponding measured value of the measured parameter of interest associated with each of the plurality of instances of the historical version of the semiconductor structure by a high-throughput, in-line production metrology system, [^{REF}POI_{PRESENT}]^{PROD-H}. This measurement data pair, [^{MEAS}S_{PRESENT}, ^{REF}POI_{PRESENT}]^{PROD-H}, is derived from high-throughput, in-line measurements of historical instances of the structure of interest fabricated on one or more production wafers in the present state.

Typically, measurement data pair, [^{MEAS}S_{PRESENT}, ^{REF}POI_{PRESENT}]^{PROD-H} is a very large data set collected using one or more instances of a high-throughput measurement system, e.g., a high-throughput optical critical dimension (OCD) measurement system such as the spectroscopic ellipsometry system depicted in FIG. 1. In general, however, any suitable high-throughput measurement system may be employed to generate measurement data pair, [^{MEAS}S_{PRESENT}, ^{REF}POI_{PRESENT}]^{PROD-H}. Historical, production wafers (PROD-H) are typically in-line, production wafers measured in relatively high volume compared to actual reference measurements of DOE wafers. Although, the design revision, process revision, or both, associated with the historical version is not exactly the same as the current version of the structure of interest, this historical training data is available in very large volumes, validated, and correlated with the current version. This enables training with a large training data set that would otherwise be impractical to generate based on actual reference measurements. As such, this historical training data contributes to the training of a present state measurement model that reliably performs measurements of structures fabricated within the expected process window during high volume production.

In some embodiments, training data set 165 includes synthetically generated, raw measurement signals, [^{SYN}S_{PRESENT}]^{DOE}, corresponding to each of a plurality of assumed values of a parameter of interest, [^{KWN}POI_{PRESENT}]^{DOE}, characterizing the current version of the semiconductor structure in the present process state, and training data set 166 includes the assumed values of the parameter of interest, [^{KWN}POI_{PRESENT}]^{DOE}. The measurement data pair, [^{SYN}S_{PRESENT}, ^{KWN}POI_{PRESENT}]^{DOE}, is generated by a measurement system model that simulates raw measurement signals generated by a high-throughput measurement system, e.g., spectroscopic ellipsometer 101 depicted in FIG. 1, associated with a measurement of a structure having assumed geometry, including assumed values of the parameter of interest. Although, the synthetically generated training data is simulated and does not perfectly replicate the measured response from a fabricated instance of the current version of the structure of interest, the synthetic training data can be generated in relatively large volume at low cost and is correlated with the current version. As such, the synthetically generated training data contributes to the training of a present state measurement model that reliably performs measurements of structures fabricated within the expected process window during high volume production.

In some embodiments, training data set 165 includes raw measurement signals associated with a measurement of each of a plurality of instances of the current version of the semiconductor structure in a prior process state, [^{MEAS}S_{PRIOR-I}]^{DOE}, and training data set 166 includes a corresponding measured value of the parameter of interest associated with a reference measurement of each of the plurality of instances of the current version of the semiconductor structure by a reference metrology system, [^{REF}POI_{PRIOR-I}]^{DOE}. This measurement data pair, [^{MEAS}S_{PRIOR-I}, ^{REF}POI_{PRIOR-I}]^{DOE}, is derived from measurements of instances of the structure of interest fabricated on one or more Design Of Experiments (DOE) wafers in a prior process state, prior process state, i. The DOE wafers are typically off-line wafers purposely fabricated with variations in process parameters to probe the expected process space and ensure that the measurement model is trained to reliably perform measurements of structures fabricated within the expected process window during high volume production.

In general, training data sets 165 and 166 include training data associated with measurements and reference measurements, respectively, associated with the current version of the semiconductor structure of interest at any number of prior process steps. Each of the different prior states of the semiconductor process flow and the present state of the semiconductor process flow are separated by one or more intervening semiconductor manufacturing process steps. Furthermore, each of the different prior states of the semiconductor process flow and any other of the different prior states are separated by one or more intervening semiconductor manufacturing process steps.

Although, a semiconductor structure of interest at a present state is not identically formed at a prior state, the prior state training data is available, validated, and correlated with the current version. As such, the prior state training data contributes to the training of a present state measurement model that reliably performs measurements of structures fabricated within the expected process window during high volume production.

In some embodiments, training data set 165 includes synthetically generated, raw measurement signals, [^{SYN}S_{PRIOR-I}]^{DOE}, corresponding to each of a plurality of assumed values of a parameter of interest, [^{KWN}POI_{PRIOR-I}]^{DOE}, characterizing the current version of the semiconductor structure in a prior process state, and training data set 166 includes the assumed values of the parameter of interest, [^{KWN}POI_{PRIOR-I}]^{DOE}. The measurement data pair, [^{SYN}S_{PRIOR-I}, ^{KWN}POI_{PRIOR-I}]^{DOE}, is generated by a measurement system model that simulates raw measurement signals generated by a high-throughput measurement system, e.g., spectroscopic ellipsometer 101 depicted in FIG. 1, associated with a measurement of a structure having assumed geometry, including assumed values of a parameter of interest in a prior process state. Although, the synthetically generated training data is simulated and does not perfectly replicate the measured response from a fabricated instance of the current version of the structure of interest, the synthetic training data can be generated in relatively large volume at low cost and is correlated with the current version. As such, the synthetically generated training data contributes to the training of a present state measurement model that reliably performs measurements of structures fabricated within the expected process window during high volume production.

In some embodiments, training data set 165 includes raw measurement signals associated with a measurement of each of a plurality of instances of a historical version of the semiconductor structure in a prior process state, [^{MEAS}S_{PRIOR-I}]^{DOE-H}, and training data set 166 includes a corresponding measured value of the parameter of interest associated with a reference measurement of each of the plurality of instances of the historical version of the semiconductor structure in the prior process state by a reference metrology system, [^{REF}POI_{PRIOR-I}]^{DOE-H}. This measurement data pair, [^{MEAS}S_{PRIOR-I}, ^{REF}POI_{PRIOR-I}]^{DOE-H}, is derived from measurements of historical instances of the structure of interest fabricated on one or more historical, Design Of Experiments (DOE-H) wafers in the prior state. The DOE-H wafers are typically off-line wafers purposely fabricated with variations in process parameters to probe the expected process space during measurement recipe development for a historical version of the structure of interest in the prior state. Although, the design revision, process revision, or both, associated with the historical version is not exactly the same as the current version of the structure of interest, and a semiconductor structure of interest at a present state is not identically formed at a prior state, the historical, prior state training data is available, validated, and correlated with the current version. As such, the historical, prior state training data contributes to the training of a present state measurement model that reliably performs measurements of structures fabricated within the expected process window during high volume production.

In some embodiments, training data set 165 includes raw measurement signals associated with a measurement of each of the plurality of instances of a historical version of the semiconductor structure in the present process state, [^{MEAS}S_{PRIOR-I}]^{PROD-H}, and training data set 166 includes a corresponding measured value of the measured parameter of interest associated with each of the plurality of instances of the historical version of the semiconductor structure by a high-throughput, in-line production metrology system, [^{REF}POI_{PRIOR-I}]^{PROD-H}. This measurement data pair, [^{MEAS}S_{PRIOR-I}, ^{REF}POI_{PRIOR-I}]^{PROD-H}, is derived from high-throughput, in-line measurements of historical instances of the structure of interest fabricated on one or more production wafers in the i^{th} prior state, where i is any non-zero positive integer number bounded by the total number of prior process states before the present process state in the semiconductor fabrication process flow.

Typically, measurement data pair, [^{MEAS}S_{PRIOR-I}, ^{REF}POI_{PRIOR-I}]^{PROD-H} is a very large data set collected using one or more instances of a high-throughput measurement system, e.g., a high-throughput optical critical dimension (OCD) measurement system such as the spectroscopic ellipsometry system depicted in FIG. 1. In general, however, any suitable high-throughput measurement system may be employed to generate measurement data pair, [^{MEAS}S_{PRIOR-I}, ^{REF}POI_{PRIOR-I}]^{PROD-H}. Historical, production wafers (PROD-H) are typically in-line, production wafers measured in relatively high volume compared to actual reference measurements of DOE-H wafers. Although, the design revision, process revision, or both, associated with the historical version is not exactly the same as the current version of the structure of interest, and a semiconductor structure of interest at a present state is not identically formed at a prior state, the historical, prior state training data is available, validated, and correlated with the current version. This enables training with a large training data set that would otherwise be impractical to generate based on actual reference measurements. As such, this historical, prior state training data contributes to the training of a present state measurement model that reliably performs measurements of structures fabricated within the expected process window during high volume production.

In general, training data sets 165 and 166 include training data associated with historical, prior state measurements at any number of prior process steps. Each of the different prior states of the semiconductor process flow and the present state of the semiconductor process flow are separated by one or more intervening semiconductor manufacturing process steps. Furthermore, each of the different prior states of the semiconductor process flow and any other of the different prior states are separated by one or more intervening semiconductor manufacturing process steps.

In some examples, training data continues to be generated based on reliable, high-throughput, in-line measurements of a continuously growing number of instances of a structure of interest at a prior state, e.g., [^{MEAS}S_{PRIOR-I}, ^{REF}POI_{PRIOR-I}]^{PROD-H}, along with corresponding high-throughput, in-line measurement signals in the present state, e.g., [^{MEAS}S_{PRESENT}, ^{REF}POI_{PRESENT}]^{PROD-H}. In these examples, prior state and present state measurements continue to be collected from in-line, production wafers. As described hereinbefore, the prior state and present state measurements are communicated to present state measurement model training engine 160. Periodically, the expanded set of training data is employed to retrain the present state measurement model to continuously improve the accuracy and reliability of the trained present state measurement model as production continues.

In a further aspect, present state measurement model training engine 160 includes a weighting module (not shown) that assigns different weighting values to different sets of training data, e.g., any of the different set of training data depicted in FIG. 3. The relative weighting of different sets of training data emphasizes training data sets assigned a relatively high weighting and deemphasizes training data sets assigned a relatively low weighting. In this manner, training data sets associated with a higher level of trust in the data or higher correlation to the current version of the structure of interest in the present state are emphasized over training data sets that are less trusted or have lower correlation to the current version of the structure of interest in the present state.

In the example, depicted in FIG. 3, weighting values, W 167, are communicated to error evaluation module 162. In one example, actual, present state reference measurement values, ^{REF}POI_{PRESENT}, and corresponding measurement signals associated with measurement of the reference structures by a high-throughput measurement system, ^{MEAS}S_{PRESENT}, are assigned a relatively high weighting compared to synthetic training data set [^{SYN}S_{PRESENT}, ^{KWN}POI_{PRESENT}]^{DOE} for purposes of training.

In other examples, training data sets including actual reference measurement data associated with measurements of the current version in the present state are weighted higher than training data sets including synthetically generated data, historical data, prior state data, and historical, prior state data.

In general, any relative weighting among the training data sets may be contemplated within the scope of this patent document.

In general, there must be a process correlation between historical and prior state training data and the current version in a present state. This correlation must be captured by the high-throughput measurement signals associated with measurements of different versions, at different states, or both. In this manner, process correlation between steps enables improved solution accuracy and robustness.

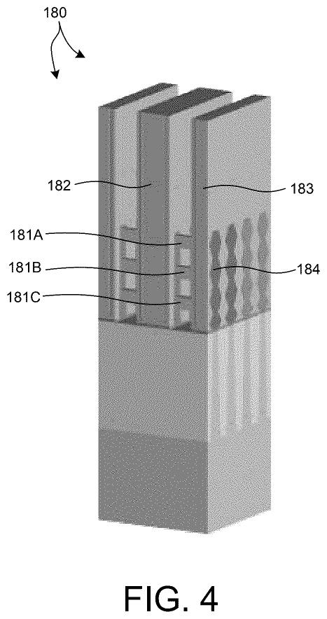

FIG. 4 depicts a nanowire based semiconductor structure 180. Structure 180 includes nanowires 181A-C, source/drain structures 182 and 183, and dielectric material 184. As illustrated in FIG. 4, nanowires 181A-C extend unsupported between source/drain structures 182 and 183. As a result, there are voids between adjacent nanowires.

The shape of a nanowire or nanosheet affects device performance significantly. Furthermore, the shape of a nanowire or nanosheet can change from one process step to another. In one example, sacrificial Silicon Germanium sheets are removed at the nanosheet release step. In addition to the removal of the SiGe sheets, part of the interspaced Silicon layers is consumed by the Silicon Germanium removal process, and as a result, the height of the Silicon nanosheets is also reduced during the release step. This can lead to height non-uniformity among Silicon nanosheets. In addition, the underlying Silicon nanosheets are affected by various etch recipes prior to the nanosheet release step.

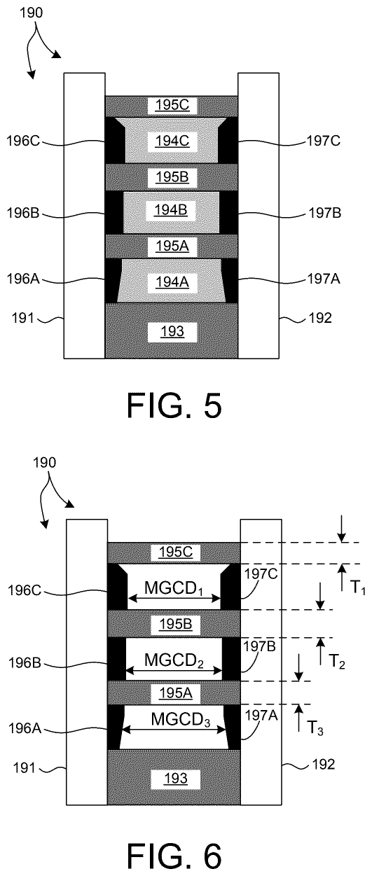

FIG. 5 is a simplified diagram illustrative of a nanosheet structure in a prior state before the Silicon Germanium (SiGe) release step. As depicted in FIG. 5, nanosheet based semiconductor structure 190 includes a SiGe source structure 191, a SiGe drain structure 192, a silicon substrate 193, and stacked Silicon nanonsheet structures 195A-C. In addition, nanosheet based semiconductor structure 190 includes inner spacer structures 196A-C attached to SiGe source structure 191 and inner spacer structures 197A-C attached to SiGe drain structure 192. Inner spacer structures 196A-C and 197A-C are located below silicon nanosheet structures 195A-C, respectively. Finally, SiGe material occupies the spaces 194A-194C between silicon substrate 193 and silicon nanosheets 195A-C, respectively. Furthermore, spaces 194A-194C are bounded by inner spacer structures 196A-C and 197A-C, respectively.

FIG. 6 is a simplified diagram illustrative of the nanosheet structure depicted in FIG. 5 in a present state after the SiGe release step. As depicted in FIG. 6, at the SiGe release step, the SiGe material occupying the spaces 194A-194C between silicon substrate 193 and silicon nanosheets 195A-C, respectively, is etched away. Several geometric parameters are critical at the present state after the SiGe release step. Exemplary critical parameters include the metal gate critical dimensions associated with each nanosheet, e.g., MGCD₁-MGCD₃, the thickness associated with each nanosheet, e.g., T₁-T₃, the shape profile of the inner spacers, the width of each nanosheet, the shape profile of each nanosheet, etc. Independent measurement of these dimensions and shape profiles is very challenging given the complexity of the structures and the relatively low volume of the critical dimensions and features.

The critical dimensions and features depicted in FIG. 6 are partially formed at the SiGe release step. However, in addition, the critical dimensions and features depicted in FIG. 6, strongly depend on previous process steps as well. In one example, the inner spacer structures are deposited and then trimmed at various epitaxial growth and strained source drain (SSD) process steps, prior the SiGe release step. In addition, a portion of the inner spacer structures is etched away at the SiGe release step. Thus, the width dimension of the inner spacer structure depends on the inner spacer dimensions at one or more prior steps, e.g., at the inner spacer deposition and inner spacer trim steps, in addition to SiGe release step.

In one example, process correlation from a prior state to a present state exists for inner spacer width between an epitaxial growth step employed from the SiGe source and drain structures 191 and 192 (prior state) and the subsequent SiGe release step (present state).

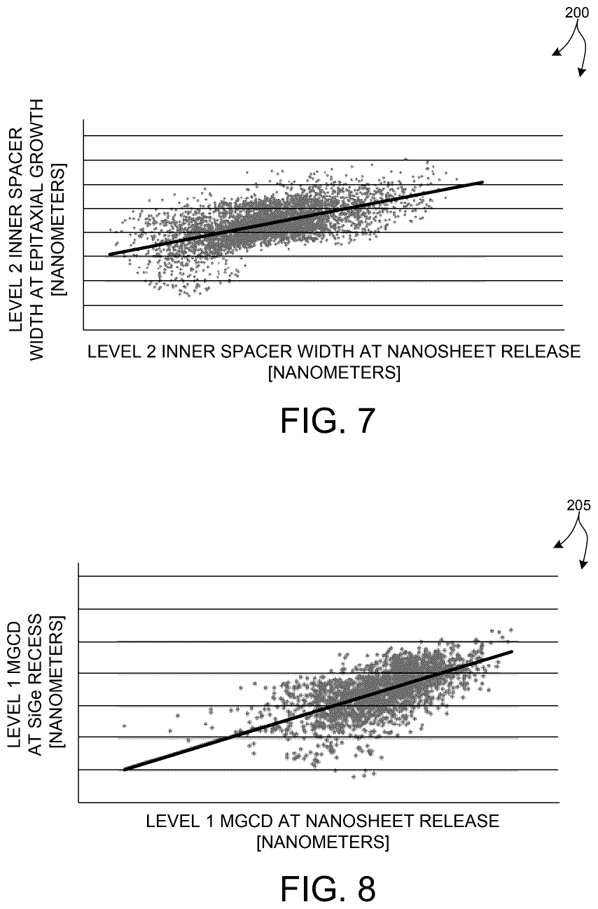

FIG. 7 is a plot 200 illustrative of correlation between the width of inner spacer structures immediately after the epitaxial growth step and immediately after the SiGe release step. As depicted in FIG. 7, the inner spacer width measured in the prior state is plotted along the y-axis and same dimension measured in the present state is plotted along the x-axis. As illustrated in FIG. 7, the correlation between the inner spacer width measured at the prior state and the present state is significant, having an R² value of 0.5 recorded on 5,000 samples.

In another example, process correlation from a prior state to a present state exists for the dimension MGCD₁ depicted in FIG. 6 between an epitaxial growth step employed to form the SiGe source and drain structures 191 and 192 (prior state) and the subsequent SiGe release step (present state).

FIG. 8 is a plot 205 illustrative of correlation between the critical dimension, MGCD₁, depicted in FIG. 6 immediately after the epitaxial growth step and immediately after the SiGe release step. As depicted in FIG. 8, MGCD₁ measured in the prior state is plotted along the y-axis and same dimension measured in the present state is plotted along the x-axis. As illustrated in FIG. 8, the correlation between MGCD₁ measured at the prior state and the present state is significant, having an R² value of 0.40 recorded on 5,000 samples.

In another example, process correlation from a prior state to a present state exists for the metal gate critical dimension, MGCD₂, depicted in FIG. 6 between an epitaxial growth step employed to form the SiGe source and drain structures 191 and 192 (prior state) and the subsequent SiGe release step (present state).

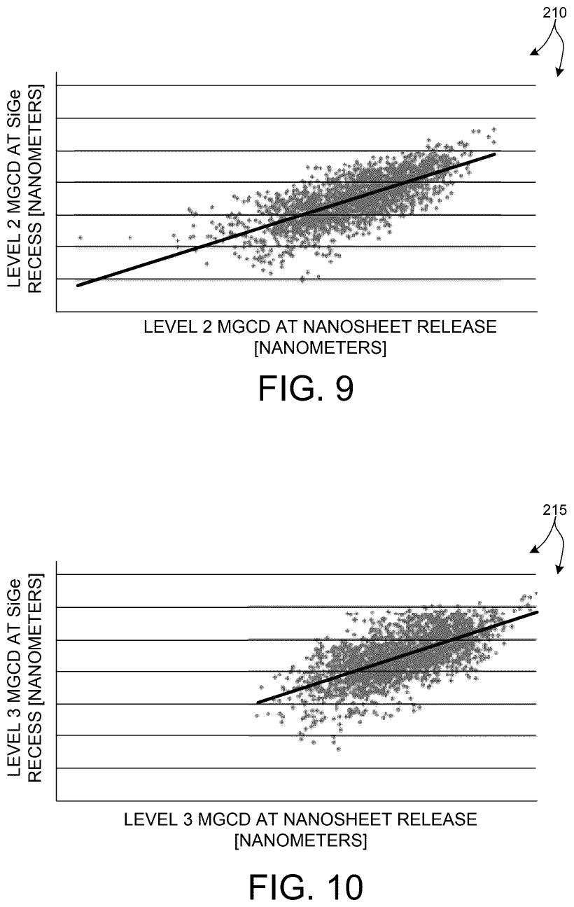

FIG. 9 is a plot 210 illustrative of correlation between the critical dimension, MGCD₂, immediately after the epitaxial growth step and immediately after the SiGe release step. As depicted in FIG. 9, MGCD₂ measured in the prior state is plotted along the y-axis and same dimension measured in the present state is plotted along the x-axis. As illustrated in FIG. 9, the correlation between MGCD₂ measured at the prior state and the present state is significant, having an Re value of 0.53 recorded on 5,000 samples.

In another example, process correlation from a prior state to a present state exists for the metal gate critical dimension, MGCD₃, depicted in FIG. 6 between an epitaxial growth step employed to form the SiGe source and drain structures 191 and 192 (prior state) and the subsequent SiGe release step (present state).

FIG. 10 is a plot 215 illustrative of correlation between the critical dimension, MGCD₃, immediately after the epitaxial growth step and immediately after the SiGe release step. As depicted in FIG. 10, MGCD₃ measured in the prior state is plotted along the y-axis and same dimension measured in the present state is plotted along the x-axis. As illustrated in FIG. 10, the correlation between MGCD₃ measured at the prior state and the present state is significant, having an Re value of 0.43 recorded on 5,000 samples.

In general, present state and historical training data are employed to generate measurement models of film structures and critical dimension structures, including, but not limited to, complex memory structures, e.g., 3D flash memory, DRAM cells, multi-deck VNAND structures, etc., and complex logic structures cells, e.g., Gate-All-Around structures, forksheet structures, complementary field effect transistor (CFET) structures, etc.

The flexibility of building measurement models using historical training data enables rapid measurement recipe generation based on relatively large data sets, including data sets acquired during production. This allows fabrication facilities to quickly refine process conditions to improve yield of FinFET structures, Gate-All-Around structures, DRAM and VNAND memory structures, etc. In many cases, the only other available alternatives to measurement of these high aspect ratio structures are destructive techniques, such as Focused Ion Beam microscopy, and extremely low throughput techniques, such as Transmission Electron Microscopy (TEM).

It should be recognized that the various steps described throughout the present disclosure may be carried out by single computer systems 116, or, alternatively, multiple computer systems 116. Moreover, different subsystems of system 100, such as the spectroscopic ellipsometer 101, may include a computer system suitable for carrying out at least a portion of the steps described herein. Therefore, the aforementioned description should not be interpreted as a limitation on the present invention but merely an illustration. Further, the one or more computing systems 116 may be configured to perform any other step(s) of any of the method embodiments described herein.

The computing system 116 may include, but is not limited to, a personal computer system, mainframe computer system, cloud-based computing system, workstation, image computer, parallel processor, or any other device known in the art. In general, the term “computing system” may be broadly defined to encompass any device having one or more processors, which execute instructions from a memory medium. In general, computing system 116 may be integrated with a measurement system such as measurement system 100, or alternatively, may be separate from any measurement system. In this sense, computing system 116 may be remotely located and receive measurement data from any measurement source.

Program instructions 120 implementing methods such as those described herein may be transmitted over or stored on carrier medium 118. The carrier medium may be a transmission medium such as a wire, cable, or wireless transmission link. The carrier medium may also include a computer-readable medium such as a read-only memory, a random access memory, a magnetic or optical disk, or a magnetic tape.

Although the methods discussed herein are explained with reference to system 100, any optical or x-ray metrology system configured to illuminate and detect light reflected, transmitted, or diffracted from a specimen may be employed to implement the exemplary methods described herein. Exemplary systems include an angle-resolved reflectometer, a scatterometer, a reflectometer, an ellipsometer, a spectroscopic reflectometer or ellipsometer, a beam profile reflectometer, a multi-wavelength, two-dimensional beam profile reflectometer, a multi-wavelength, two-dimensional beam profile ellipsometer, a rotating compensator spectroscopic ellipsometer, an optically modulated reflectometer, an optically modulated ellipsometer, a transmissive x-ray scatterometer, a reflective x-ray scatterometer, etc. By way of non-limiting example, an ellipsometer may include a single rotating compensator, multiple rotating compensators, a rotating polarizer, a rotating analyzer, a modulating element, multiple modulating elements, or no modulating element.

It is noted that the output from a measurement system may be configured in such a way that the measurement system uses more than one technology. In fact, an application may be configured to employ any combination of available metrology sub-systems within a single tool, or across a number of different tools.

A system implementing the methods described herein may also be configured in a number of different ways. For example, a wide range of wavelengths (including visible, ultraviolet, infrared, and X-ray), angles of incidence, states of polarization, and states of coherence may be contemplated. In another example, the system may include any of a number of different light sources (e.g., a directly coupled light source, a laser-sustained plasma light source, etc.). In another example, the system may include elements to condition light directed to or collected from the specimen (e.g., apodizers, filters, etc.).

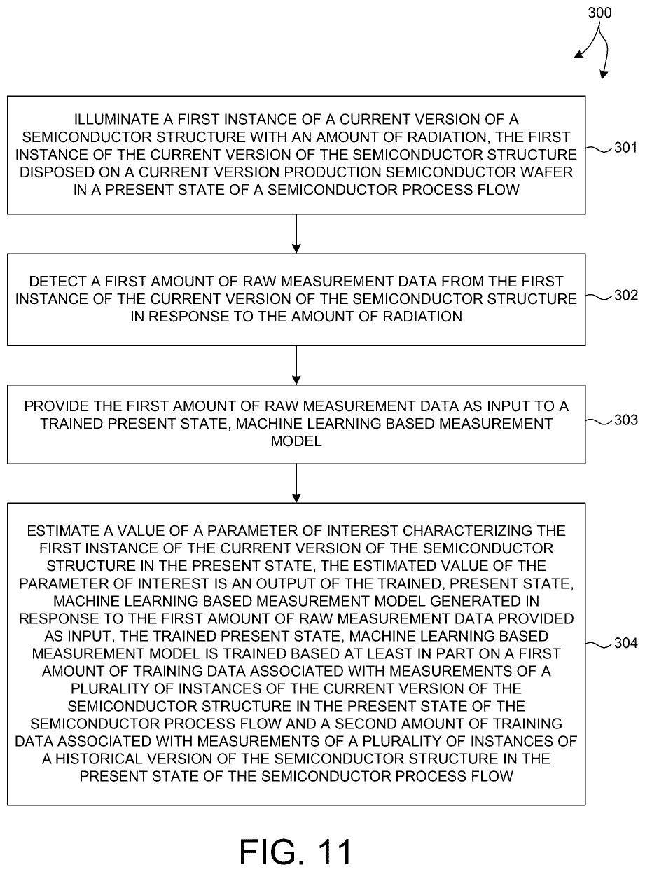

FIG. 11 illustrates a method 300 suitable for implementation by metrology system 100 of the present invention. In one aspect, it is recognized that data processing blocks of method 300 may be carried out via a pre-programmed algorithm executed by one or more processors of computing system 116. While the following description is presented in the context of metrology system 100, it is recognized herein that the particular structural aspects of metrology system 100 do not represent limitations and should be interpreted as illustrative only.

In block 301, a first instance of a current version of a semiconductor structure is illuminated with an amount of radiation. The first instance of the current version of the semiconductor structure is disposed on a current version production semiconductor wafer in a present state of a semiconductor process flow.

In block 302, a first amount of raw measurement data is detected from the first instance of the current version of the semiconductor structure in response to the amount of radiation.

In block 303, the first amount of raw measurement data is provided as input to a trained present state, machine learning based measurement model.

In block 304, a value of a parameter of interest characterizing the first instance of the current version of the semiconductor structure in the present state is estimated. The estimated value of the parameter of interest is an output of the trained, present state, machine learning based measurement model generated in response to the first amount of raw measurement data provided as input. The trained present state, machine learning based measurement model is trained based at least in part on a first amount of training data associated with measurements of a plurality of instances of the current version of the semiconductor structure in the present state of the semiconductor process flow and a second amount of training data associated with measurements of a plurality of instances of a historical version of the semiconductor structure in the present state of the semiconductor process flow.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), a displacement between two or more structures (e.g., overlay displacement between overlaying grating structures, etc.), and a dispersion property value of a material used in the structure or part of the structure. Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect. However, such terms of art do not limit the scope of the term “metrology system” as described herein. In addition, the metrology system 100 may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the calibration of system parameters based on critical dimension data.

Various embodiments are described herein for a semiconductor processing system (e.g., an inspection system or a lithography system) that may be used for processing a specimen. The term “specimen” is used herein to refer to a site, or sites, on a wafer, a reticle, or any other sample that may be processed (e.g., printed or inspected for defects) by means known in the art. In some examples, the specimen includes a single site having one or more measurement targets whose simultaneous, combined measurement is treated as a single specimen measurement or reference measurement. In some other examples, the specimen is an aggregation of sites where the measurement data associated with the aggregated measurement site is a statistical aggregation of data associated with each of the multiple sites. Moreover, each of these multiple sites may include one or more measurement targets associated with a specimen or reference measurement.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A measurement system comprising:
an illumination subsystem configured to illuminate a first instance of a current version of a semiconductor structure with an amount of radiation, the first instance of the current version of the semiconductor structure disposed on a current version production semiconductor wafer in a present state of a semiconductor process flow;
a detector configured to detect a first amount of raw measurement data from the first instance of the current version of the semiconductor structure in response to the amount of radiation; and
a computing system configured to:
provide the first amount of raw measurement data as input to a trained present state, machine learning based measurement model; and
estimate a value of a parameter of interest characterizing the first instance of the current version of the semiconductor structure in the present state, the estimated value of the parameter of interest is an output of the trained, present state, machine learning based measurement model generated in response to the first amount of raw measurement data provided as input, the trained present state, machine learning based measurement model is trained based at least in part on a first amount of training data associated with measurements of a plurality of instances of the current version of the semiconductor structure in the present state of the semiconductor process flow and a second amount of training data associated with measurements of a plurality of instances of a historical version of the semiconductor structure in the present state of the semiconductor process flow.

2. The measurement system of claim 1, wherein the historical version of the semiconductor structure differs from the current version of the semiconductor structure in a design revision, a process recipe, or both.

3. The measurement system of claim 1, wherein the first amount of training data includes a set of raw measurement signals associated with a measurement of each of the plurality of instances of the current version of the semiconductor structure in the present process state and a corresponding measured value of the parameter of interest associated with a reference measurement of each of the plurality of instances of the current version of the semiconductor structure by a reference metrology system.

4. The measurement system of claim 3, wherein the first amount of training data also includes a set of synthetic, raw measurement signals corresponding to each of a plurality of assumed values of the parameter of interest characterizing the current version of the semiconductor structure in the present process state.

5. The measurement system of claim 1, the trained present state, machine learning based measurement model is further trained based at least in part on a third amount of training data associated with measurements of a plurality of instances of the current version of the semiconductor structure, each of the plurality of instances of the current version of semiconductor structure in one of a plurality of different prior states of the semiconductor process flow, wherein each of the different prior states of the semiconductor process flow and the present state of the semiconductor process flow are separated by one or more intervening semiconductor manufacturing process steps.

6. The measurement system of claim 5, wherein the third amount of training data also includes a set of synthetic, raw measurement signals corresponding to each of a plurality of assumed values of the parameter of interest characterizing the current version of the semiconductor structure in the one or more prior process states.

7. The measurement system of claim 1, the trained present state, machine learning based measurement model is further trained based at least in part on a third amount of training data associated with measurements of each of a plurality of instances of the historical version of the semiconductor structure in one of a plurality of different prior states of the semiconductor process flow, wherein each of the different prior states of the semiconductor process flow and the present state of the semiconductor process flow are separated by one or more intervening semiconductor manufacturing process steps.

8. The measurement system of claim 7, wherein the third amount of training data includes a set of raw measurement signals associated with a measurement of each of the plurality of instances of the historical version of the semiconductor structure and a corresponding measured value of the parameter of interest associated with a reference measurement of each of the plurality of instances of the historical version of the semiconductor structure by a reference metrology system.

9. The measurement system of claim 7, wherein the third amount of training data includes a set of raw measurement signals associated with a measurement of each of the plurality of instances of the historical version of the semiconductor structure and a corresponding estimated value of a parameter of interest associated with a measurement of each of the plurality of instances of the historical version of the semiconductor structure.

10. The measurement system of claim 7, wherein the plurality of instances of the historical version of the semiconductor structure in one of a plurality of different prior states of the semiconductor process flow are fabricated on one or more in-line, production wafers.

11. The measurement system of claim 1, wherein the semiconductor structure is a critical dimension structure or a film structure.

12. The measurement system of claim 1, wherein the amount of radiation includes electromagnetic energy in an x-ray range or an optical range.

13. A method comprising:
illuminating a first instance of a current version of a semiconductor structure with an amount of radiation, the first instance of the current version of the semiconductor structure disposed on a current version production semiconductor wafer in a present state of a semiconductor process flow;
detecting a first amount of raw measurement data from the first instance of the current version of the semiconductor structure in response to the amount of radiation;
providing the first amount of raw measurement data as input to a trained present state, machine learning based measurement model; and
estimating a value of a parameter of interest characterizing the first instance of the current version of the semiconductor structure in the present state, the estimated value of the parameter of interest is an output of the trained, present state, machine learning based measurement model generated in response to the first amount of raw measurement data provided as input, the trained present state, machine learning based measurement model is trained based at least in part on a first amount of training data associated with measurements of a plurality of instances of the current version of the semiconductor structure in the present state of the semiconductor process flow and a second amount of training data associated with measurements of a plurality of instances of a historical version of the semiconductor structure in the present state of the semiconductor process flow.

14. The method of claim 13, wherein the historical version of the semiconductor structure differs from the current version of the semiconductor structure in a design revision, a process recipe, or both.

15. The method of claim 13, wherein the first amount of training data includes a set of raw measurement signals associated with a measurement of each of the plurality of instances of the current version of the semiconductor structure in the present process state and a corresponding measured value of the parameter of interest associated with a reference measurement of each of the plurality of instances of the current version of the semiconductor structure by a reference metrology system.

16. The method of claim 13, the trained present state, machine learning based measurement model is further trained based at least in part on a third amount of training data associated with measurements of a plurality of instances of the current version of the semiconductor structure, each of the plurality of instances of the current version of semiconductor structure in one of a plurality of different prior states of the semiconductor process flow, wherein each of the different prior states of the semiconductor process flow and the present state of the semiconductor process flow are separated by one or more intervening semiconductor manufacturing process steps.

17. The method of claim 13, the trained present state, machine learning based measurement model is further trained based at least in part on a third amount of training data associated with measurements of each of a plurality of instances of the historical version of the semiconductor structure in one of a plurality of different prior states of the semiconductor process flow, wherein each of the different prior states of the semiconductor process flow and the present state of the semiconductor process flow are separated by one or more intervening semiconductor manufacturing process steps.

18. The method of claim 17, wherein the third amount of training data includes a set of raw measurement signals associated with a measurement of each of the plurality of instances of the historical version of the semiconductor structure and a corresponding measured value of the parameter of interest associated with a reference measurement of each of the plurality of instances of the historical version of the semiconductor structure by a reference metrology system.

19. The method of claim 17, wherein the third amount of training data includes a set of raw measurement signals associated with a measurement of each of the plurality of instances of the historical version of the semiconductor structure and a corresponding estimated value of a parameter of interest associated with a measurement of each of the plurality of instances of the historical version of the semiconductor structure.

20. A measurement system comprising:
an illumination subsystem configured to illuminate a first instance of a current version of a semiconductor structure with an amount of radiation, the first instance of the current version of the semiconductor structure disposed on a current version production semiconductor wafer in a present state of a semiconductor process flow;
a detector configured to detect a first amount of raw measurement data from the first instance of the current version of the semiconductor structure in response to the amount of radiation; and
a non-transitory, computer readable medium comprising instructions that, when executed by one or more processors, causes the one or more processors to:
provide the first amount of raw measurement data as input to a trained present state, machine learning based measurement model; and
estimate a value of a parameter of interest characterizing the first instance of the current version of the semiconductor structure in the present state, the estimated value of the parameter of interest is an output of the trained, present state, machine learning based measurement model generated in response to the first amount of raw measurement data provided as input, the trained present state, machine learning based measurement model is trained based at least in part on a first amount of training data associated with measurements of a plurality of instances of the current version of the semiconductor structure in the present state of the semiconductor process flow and a second amount of training data associated with measurements of a plurality of instances of a historical version of the semiconductor structure in the present state of the semiconductor process flow.
